(19) United States
(12) Patent Application Publication
(10) Pub. No.: US 2014/0308759 A1
(43) Pub. Date: Oct. 16, 2014

(54) METHOD OF FORMING SEMICONDUCTOR DEVICE HAVING MAGNETIC TUNNEL JUNCTION AND RELATED DEVICE

(71) Applicants: Woo-Jin KIM, Yongin-si (KR); Ki-Woong KIM, Yongin-si (KR); Young-Hyun KIM, Seoul (KR)

(72) Inventors: Woo-Jin KIM, Yongin-si (KR); Ki-Woong KIM, Yongin-si (KR); Young-Hyun KIM, Seoul (KR)

(21) Appl. No.: 14/217,917

(22) Filed: Mar. 18, 2014

(30) Foreign Application Priority Data
Apr. 12, 2013 (KR) 10-2013-0040584

(51) Int. Cl. H01L 43/14

(52) U.S. Cl. CPC H01L 43/14
USPC 438/3

(57) ABSTRACT

A method of forming a semiconductor device includes forming a perpendicular magnetized magnetic device, annealing the perpendicular magnetized magnetic device, and applying a magnetic field to the perpendicular magnetized magnetic device. The semiconductor device may be a magnetoresistance data storage device. The magnetic field is applied in a direction that is substantially perpendicular to a substrate coupled to the perpendicular magnetized magnetic device.

### CROSS-REFERENCE TO RELATED APPLICATION

Korean Patent Application No. 1-2013-0040584, filed on Apr. 12, 2013, and entitled, “Method of Forming Semiconductor Device Having Magnetic Tunnel Junction and Related Device,” is incorporated by reference herein in its entirety.

### BACKGROUND

1. Field

One or more embodiments described herein relate to a semiconductor device.

2. Description of Related Art

Research into various methods of improving the magnetoresistance ratio in semiconductor devices has been extensively conducted. Some of this research has particularly focused on Spin Transfer Torque-Magnetoresistive Random Access Memories (STT-MRAMs).

### SUMMARY

In accordance with one embodiment, a method of forming a semiconductor device includes forming a perpendicular magnetized magnetic device, annealing the perpendicular magnetized magnetic device, and applying a magnetic field to the perpendicular magnetized magnetic device, wherein the magnetic field is applied in a direction that is substantially perpendicular to a substrate coupled to the perpendicular magnetized magnetic device.

Applying the perpendicular magnetic field to the perpendicular magnetized magnetic device may include applying a first perpendicular magnetic field; and applying a second perpendicular magnetic field, wherein the first perpendicular magnetic field may be applied simultaneously with the annealing of the perpendicular magnetized magnetic device.

Forming the perpendicular magnetized magnetic device and annealing the perpendicular magnetized magnetic device may be performed using an in-situ process in a same chamber.

The perpendicular magnetic field may be performed after the annealing of the perpendicular magnetized magnetic device.

Annealing the perpendicular magnetized magnetic device and applying the perpendicular magnetic field to the perpendicular magnetized magnetic device may be performed using an in-situ process in a same chamber.

Applying the perpendicular magnetic field and annealing the perpendicular magnetized magnetic device may be performed simultaneously.

The method may include applying a horizontal magnetic field to the perpendicular magnetized magnetic device, wherein applying the horizontal magnetic field and annealing of the perpendicular magnetized magnetic device may be performed simultaneously.

The perpendicular magnetic field may lie in a range of about 0.01T to about 5T. Annealing the perpendicular magnetized magnetic device may be performed at a temperature range of about 250° C. to about 400° C.

The perpendicular magnetized magnetic device may include a pinned layer; a free layer facing the pinned layer; and a barrier layer between the pinned layer and the free layer, wherein the perpendicular magnetic field is applied in a direction substantially perpendicular to an interface between the barrier layer and the free layer.

The pinned layer may include a buffer layer; and a perpendicular magnetic anisotropy layer, wherein the buffer layer is formed between the perpendicular magnetic anisotropy layer and the barrier layer.

The free layer may include a first free layer; a second free layer; and an intermediate layer between the first free layer and the second free layer, wherein the first free layer is formed between the intermediate layer and the barrier layer.

In accordance with another embodiment, an apparatus for making a semiconductor device may include a first chamber may include substrate having a perpendicular magnetized magnetic device; and a magnetic field generation device to apply a perpendicular magnetic field to the substrate. The apparatus may further include a heater to heat the substrate.

Also, a second chamber may be separated from the first chamber and may include the substrate having the perpendicular magnetized magnetic device; and a heater to heat the substrate.

In accordance with another embodiment, a magnetoresistance storage device includes a storage layer, a reference layer, and a barrier layer between the storage and reference layers, wherein the reference layer includes a magnetic anisotropy layer having a uniaxial spin direction substantially perpendicular to at least one of a first interface between the storage layer and barrier layer or a second interface between the reference layer and barrier layer. The barrier layer may include a tunnel layer.

A spin direction of storage layer may be equal to the spin direction of the magnetic anisotropy layer. The spin direction of the storage layer may be opposite to the spin direction of the magnetic anisotropy layer. If the spin direction of the storage layer is equal to the spin direction of the magnetic anisotropy layer, the device has a first resistance. If the spin direction of the storage layer is opposite to the spin direction of the magnetic anisotropy layer, the device has a second resistance greater than the first resistance.

### BRIEF DESCRIPTION OF THE DRAWINGS

Features will become apparent to those of ordinary skill in the art by describing in detail exemplary embodiments with reference to the attached drawings in which:

FIGS. 1 to 4 illustrate embodiments of methods of forming a semiconductor device;

FIG. 5 illustrates part of the semiconductor device;

FIG. 6 illustrates an example of an equivalent circuit of part of a cell array block of the semiconductor device;

FIGS. 7-12 illustrate embodiments of a magnetic device of a semiconductor device;

FIGS. 13 to 18 illustrate equipment that may be used to form a semiconductor device according to one or more of the aforementioned embodiments; and

FIGS. 19 to 24 illustrate a system block diagrams of an electronic device according to one or more embodiments.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

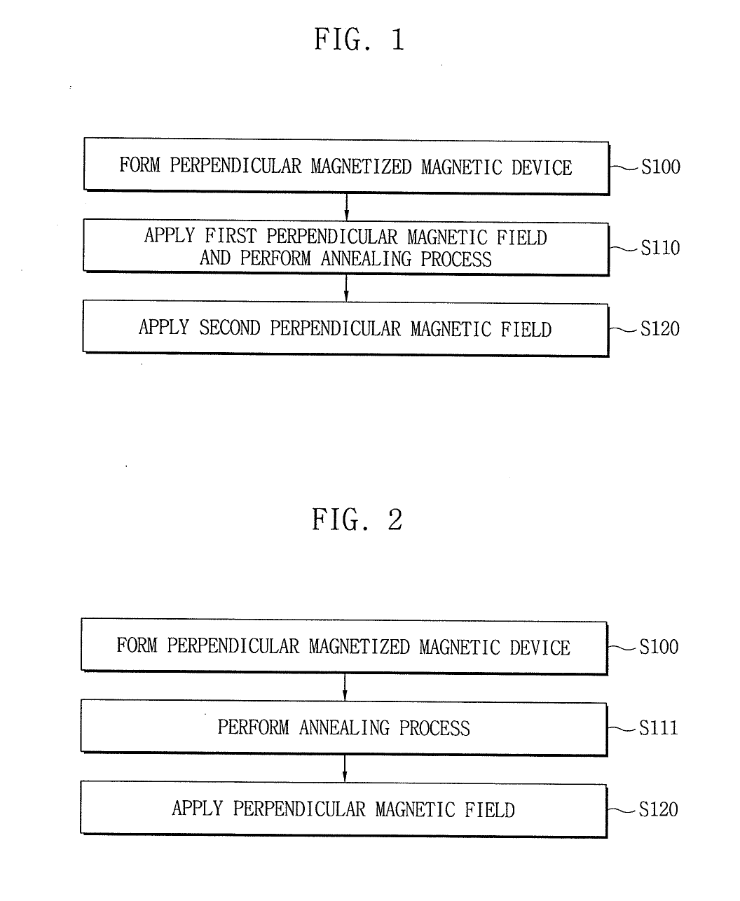

FIGS. 1 to 4 illustrate embodiments of methods of forming a semiconductor device. Referring to FIG. 1, a first method of forming a semiconductor device may include forming a perpendicular magnetized magnetic device (S100), applying a first perpendicular magnetic field and performing an annealing process (S110), and applying a second perpendicular magnetic field (S120).

Referring to FIG. 2, a second method of forming a semiconductor device may include forming a perpendicular magnetized magnetic device (S100), performing an annealing process (S111), and applying a perpendicular magnetic field (S120).

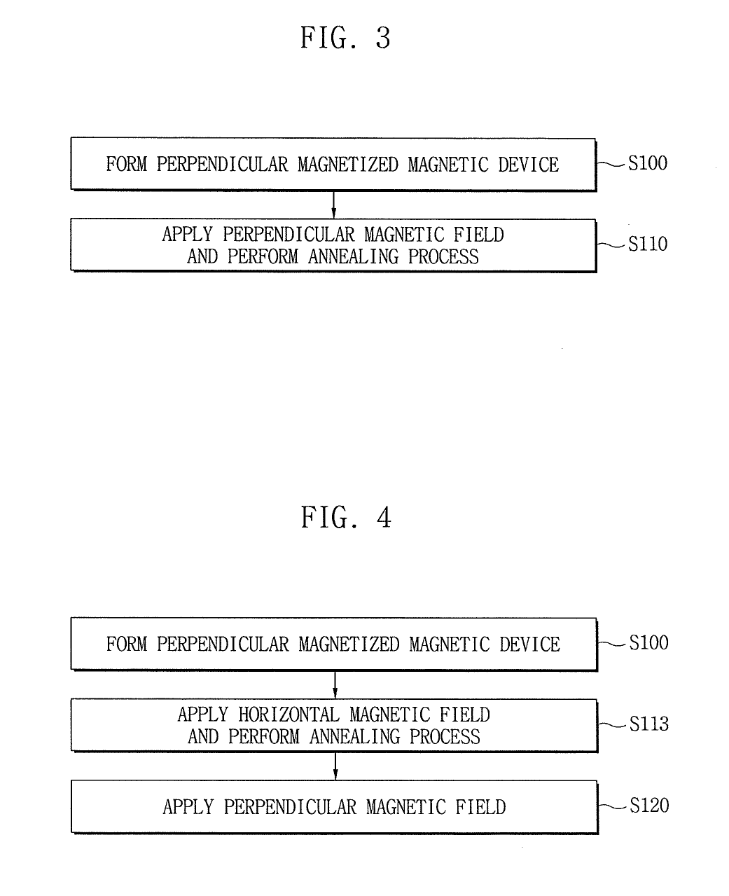

Referring to FIG. 3, a third method of forming a semiconductor device may include forming a perpendicular magnetized magnetic device (S100), and applying a perpendicular magnetic field and performing an annealing process (S110).

Referring to FIG. 4, a fourth method of forming a semiconductor device may include forming a perpendicular magnetized magnetic device (S100), applying a horizontal magnetic field and performing an annealing process (S113), and applying a perpendicular magnetic field (S120).

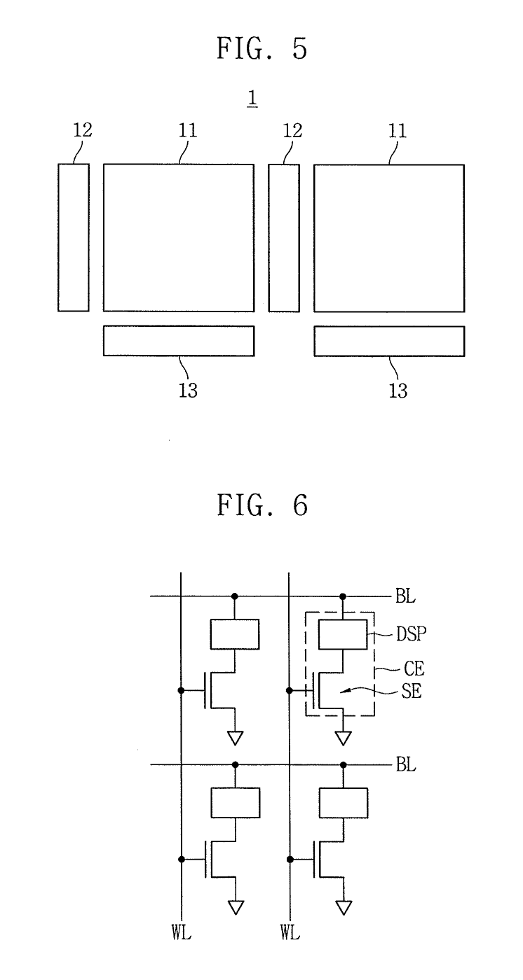

FIG. 5 illustrates an example of a part of a semiconductor device 1 formed in accordance with one or more of the aforementioned embodiments. Referring to FIG. 5, the semiconductor device 1 include a plurality of cell array blocks 11, a plurality of first decoders 12, and a plurality of second decoders 13. The first decoders 12 and the cell array blocks 11 may be alternately disposed. The second decoders 13 may be disposed on sides of respective ones of the cell array blocks 11. The first decoders 12 and the second decoders 13 may be electrically connected to the cell array blocks 11.

FIG. 6 illustrates an equivalent circuit of a part of a cell array block of the semiconductor device 1 illustrated in FIG. 5. Referring to FIGS. 5 and 6, each of the cell array blocks 11 may include a plurality of bit lines BL, a plurality of word lines WL, and a plurality of memory cells CE.

Each of the memory cells CE may include a data storage plug DSP and a switching element SE. The memory cells CE may be cells of a spin transfer torque magnetoresistive random access memory (STT-MRAM). The word lines WL may be parallel to each other, and the bit lines BL may be parallel to each other. The bit lines BL may cross the word lines WL. The memory cells CE may be formed at intersections between the bit lines BL and the word lines WL.

The data storage plug DSP may be a perpendicular magnetized magnetic device using interface perpendicular anisotropy. The data storage plug DSP may include a magnetic tunnel junction. The switching element SE may be a transistor. The drain of the switching element SE may be in contact with one end of the data storage plug DSP, and another end of the data storage plug DSP may be connected to a corresponding one of the bit lines BL. The gate electrode of the switching element SE may be connected to a corresponding one of the word lines WL. The switching element SE may function to control an electric signal flowing along the corresponding bit line BL via the data storage plug DSP.

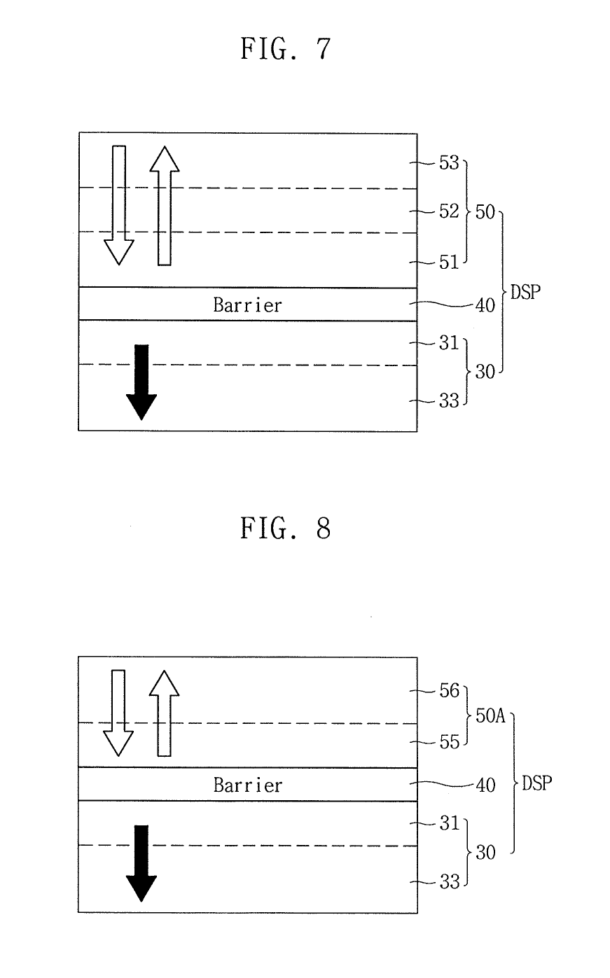

FIGS. 7 to 12 illustrate cross-sectional views of one embodiment of a magnetic device of a semiconductor device according to one or more of the aforementioned embodiments.

Referring to FIG. 7, a data storage plug DSP may include a pinned layer 30, a barrier layer 40, and a free layer 50. The pinned layer 30 may be referred to as a reference layer, and the free layer 50 may be referred to as a storage layer. The pinned layer 30 may include a first buffer layer 31 and a perpendicular magnetic anisotropy layer 33. The free layer 50 may include a first free layer 51, an intermediate layer 52, and a second free layer 53. The perpendicular magnetic anisotropy layer 33 may be connected to the switching element SE (see, e.g., FIG. 6). The second free layer 53 may be connected to a corresponding one of the bit lines BLs (see, e.g., FIG. 6).

The barrier layer 40 may be formed between the first buffer layer 31 and the first free layer 51. The barrier layer 40 may be referred to as a tunnel barrier layer or a tunnel layer. The barrier layer 40 may include, for example, a metal oxide such as MgO. The barrier layer 40 may be serve as an insulating layer. The first buffer layer 31 may be formed between the barrier layer 40 and the perpendicular magnetic anisotropy layer 33. In one embodiment, the first buffer layer 31 may be in contact with the barrier layer 40 and the perpendicular magnetic anisotropy layer 33. The first buffer layer 31 may include, for example, CoFeB, and the perpendicular magnetic anisotropy layer 33 may include, for example, CoFeTb, FePt, or Co/Pd, or a combination thereof.

The first free layer 51 may be formed between the barrier layer 40 and the intermediate layer 52. The first free layer 51 may be in contact with the barrier layer 40 and the intermediate layer 52. The intermediate layer 52 may be formed between the first free layer 51 and the second free layer 53. The intermediate layer 52 may be in contact with the first free layer 51 and the second free layer 53. The first free layer 51 may include, for example, CoFeB, CoFeNi, CoFeCr, CoFeBSi, CoFeBCr, CoFeBAl, CoFeBV, FeB, FeNi, or FeTa, or a combination thereof. The intermediate layer 52 may include, for example, Ta, W, Mo, or Nb, or a combination thereof. The second free layer 53 may include, for example, CoFeB, CoFeNi, CoFeCr, CoFeBSi, CoFeBCr, CoFeBAl, CoFeBV, FeB, FeNi, or FeTa, or a combination thereof.

Referring to FIG. 8, in accordance with another embodiment, the data storage plug DSP may include the pinned layer 30, the barrier layer 40, and a free layer 50A. The pinned layer 30 may include a first buffer layer 31 and a perpendicular magnetic anisotropy layer 33. The free layer 50A may include a second buffer layer 55 and a third free layer 56.

The second buffer layer 55 may be formed between the barrier layer 40 and the third free layer 56. The second buffer layer 55 may be in contact with the barrier layer 40 and the third free layer 56. The third free layer 56 may be connected to a corresponding one of the bit lines BL (see, e.g., FIG. 6). The second buffer layer 55 may include, for example, CoFeB. The third free layer 56 may include, for example, CoFeB, CoFeNi, CoFeCr, CoFeBSi, CoFeBCr, CoFeBAl, CoFeBV, FeB, FeNi, FeTa, Ta, W, Mo, or Nb, or a combination thereof. The third free layer 56 may be formed of a single layer or multilayer.

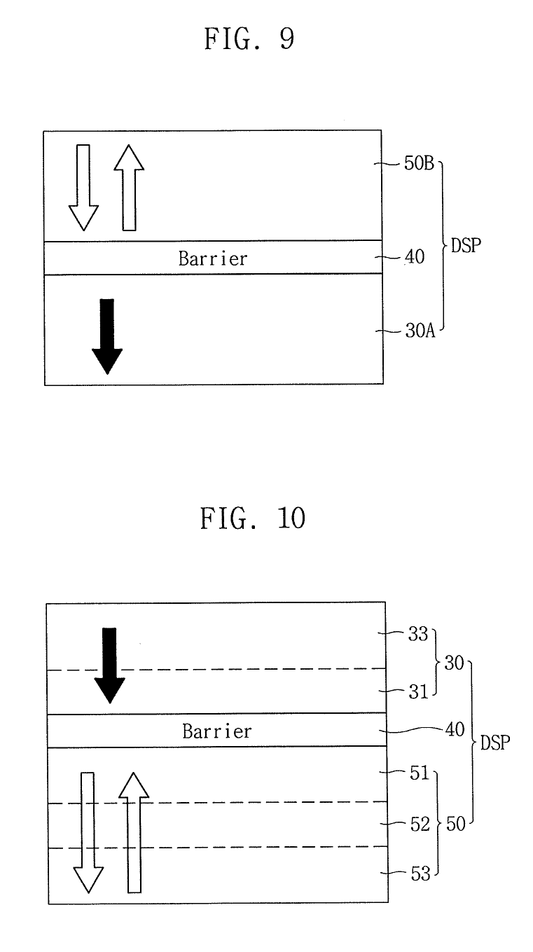

Referring to FIG. 9, in accordance with another embodiment, a data storage plug DSP may include a pinned layer 30A, the barrier layer 40, and a free layer 50B. The barrier layer 40 may be formed between the pinned layer 30A and the free layer 50B. The barrier layer 40 may be in contact with the pinned layer 30A and the free layer 50B. The pinned layer 30A may be connected to the switching element SE (see, e.g., FIG. 6). The free layer 50B may be connected to a corresponding one of the bit lines BL (see, e.g., FIG. 6).

The pinned layer 30A may include, for example, CoFeTb, FePt, Co/Pd, or CoFeB, or a combination thereof. The free layer 50B may include, for example, CoFeB, CoFeNi, CoFeCr, CoFeBSi, CoFeBCr, CoFeBAl, CoFeBV, FeB, FeNi, FeTa, Ta, W, Mo, or Nb, or a combination thereof. One or more electrode layers may be formed at a lower part of the pinned layer 30A, and a capping layer and one or more other electrode layers may be formed at an upper part of the free layer 50B.

Referring to FIG. 10, according to another embodiment, the data storage plug DSP may include the pinned layer 30, the barrier layer 40, and the free layer 50. The pinned layer 30 may include a first buffer layer 31 and a perpendicular magnetic anisotropy layer 33. The free layer 50 may include a first free layer 51, an intermediate layer 52, and a second free layer 53.

The barrier layer 40 may be formed between the first buffer layer 31 and the first free layer 51. The first buffer layer 31 may be formed between the barrier layer 40 and the perpendicular magnetic anisotropy layer 33. The perpendicular magnetic anisotropy layer 33 may be connected to a corresponding one of the bit lines BL (see e.g., FIG. 6). The intermediate layer 52 may be formed between the first free layer 51 and the second free layer 53. The second free layer 53 may be connected to the switching element SE (see, e.g., FIG. 6).

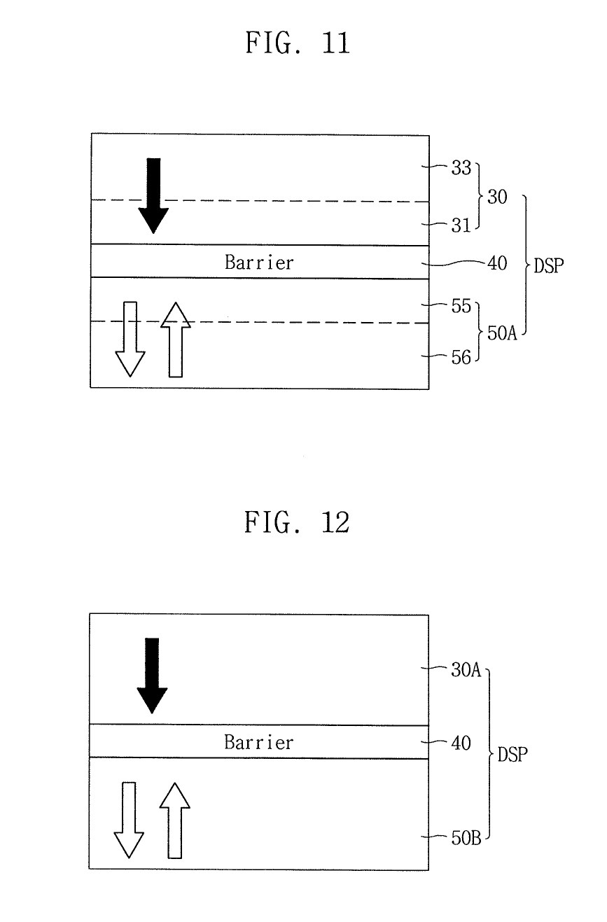

Referring to FIG. 11, in accordance with another embodiment, a data storage plug DSP may include the pinned layer 30, the barrier layer 40, and the free layer 50A. The pinned layer 30 may include a first buffer layer 31 and a perpendicular magnetic anisotropy layer 33. The free layer 50A may include a second buffer layer 55 and a third free layer 56. The barrier layer 40 may be formed between the first buffer layer 31 and the second free layer 55. The second buffer layer 55 may be formed between the barrier layer 40 and the third free layer 56. The third free layer 56 may be connected to the switching element SE (see e.g., FIG. 6).

Referring to FIG. 12, in accordance with another embodiment, the data storage plug DSP may include the pinned layer 30A, the barrier layer 40, and the free layer 50B. The data storage plug DSP may be interpreted as a perpendicular magnetized magnetic device. The free layer 50B may be connected to the switching element SE (see e.g., FIG. 6). The pinned layer 30A may be connected to a corresponding one of the bit lines BL (see e.g., FIG. 6).

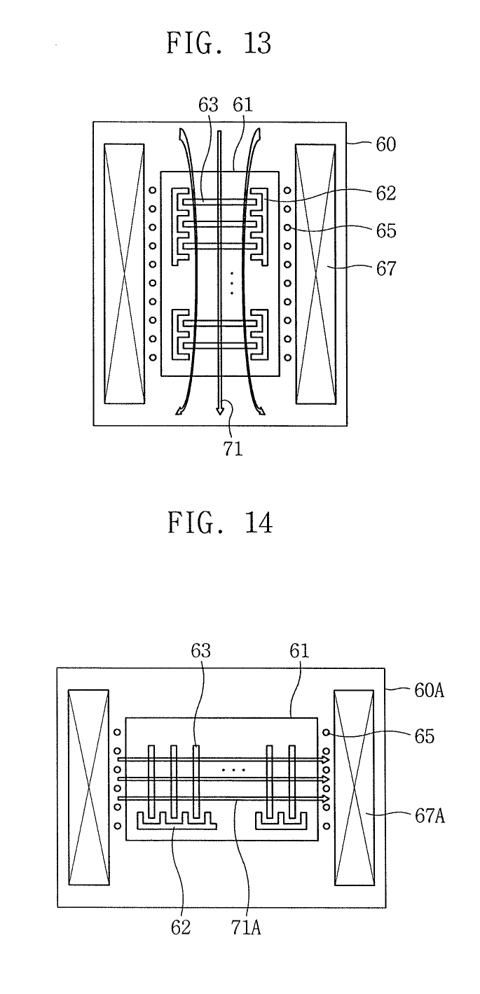

FIGS. 13 to 18 illustrate one or more embodiments of equipment used to form a semiconductor device according to one or more of the aforementioned embodiments. Referring to FIG. 13, equipment 60 may include a chamber 61, a heating device 65, and a magnetic field generation device 67. Magazines 62 on which a plurality of wafers 63 are mounted may be included in the chamber 61.

The chamber 61 may be a vacuum chamber with, for example, a vacuum of about 1E-7 Torr. The wafers 63 may be in a state in which the data storage plug DSP and the switching element SE described with reference to FIGS. 5 to 12 are formed. The data storage plug DSP and the switching element SE may be formed on surfaces of the wafers 63. For example, the switching element SE and the word lines WL may be formed on a front surface of each wafer 63. The data storage plug DSP may be formed on the switching element SE. The bit lines BL crossing the word lines WL may be formed on the data storage plugs DSP. The wafers 63 may serve as a semiconductor substrate. In other embodiments, the wafers 63 may be replaced with a glass substrate, a printed circuit board, or a combination thereof.

The magazine 62 may include quartz, metals, ceramic, or engineering plastic, or a combination thereof. The wafers 63 may be vertically mounted in the magazine 62. The front surfaces of the wafers 63 may be parallel to the horizontal direction.

The heating device 65 may be disposed close to the chamber 61. The heating device 65 may function to heat the wafers 63 to within a predetermined temperature range, for example, 250° C. to 400° C. The magnetic field generation device 67 may be disposed close to the chamber 61. In one embodiment, the magnetic field generation device 67 may be disposed on the outside of the chamber 61. The magnetic field generation device 67 may function to apply a perpendicular magnetic field 71 of a predetermined strength, e.g., 0.01T to 5T, to the wafers 63.

In one embodiment, the magnetic field generation device 67 may include an electromagnet, a permanent magnet, or a combination thereof. For example, the magnetic field generation device 67 may include an electromagnet. The perpendicular magnetic field 71 may be applied parallel to the perpendicular direction. The perpendicular magnetic field 71 may be applied in a direction perpendicular to the surfaces of the wafers 63. The perpendicular magnetic field 71 may be applied in a direction perpendicular to the surface of the data storage plug DSP.

Referring to FIG. 14, equipment 60A may include a chamber 61, a heating device 65, and a magnetic field generation device 67A. Wafers 63 may be horizontally mounted in a magazine 62. The front surfaces of the wafers 63 may be parallel to a perpendicular direction. The magnetic field generation device 67A may function to apply a perpendicular magnetic field 71A to the wafers 63. The magnetic field generation device 67A may include an electromagnet, a permanent magnet, or a combination thereof. For example, the magnetic field generation device 67A may include a permanent magnet. The perpendicular magnetic field 71A may be applied parallel to the horizontal direction. The perpendicular magnetic field 71A may be applied in a direction perpendicular to the surface of the data storage plug DSP.

Referring to FIG. 15, in accordance with one embodiment, equipment for forming the semiconductor device may include first equipment 60B and second equipment 60C. The first equipment 60B may include a first chamber 61A and a heating device 65. Magazines 62, on which a plurality of wafers 63 are mounted, may be loaded into the first chamber 61A. The second equipment 60C may include a second chamber 61 and a magnetic field generation device 67. Magazines 62 on which a plurality of wafers 63 are mounted may be loaded into the second chamber 61. The first equipment 60B may omit the magnetic field generation device 67, and the second equipment 60C may omit the heating device 65.

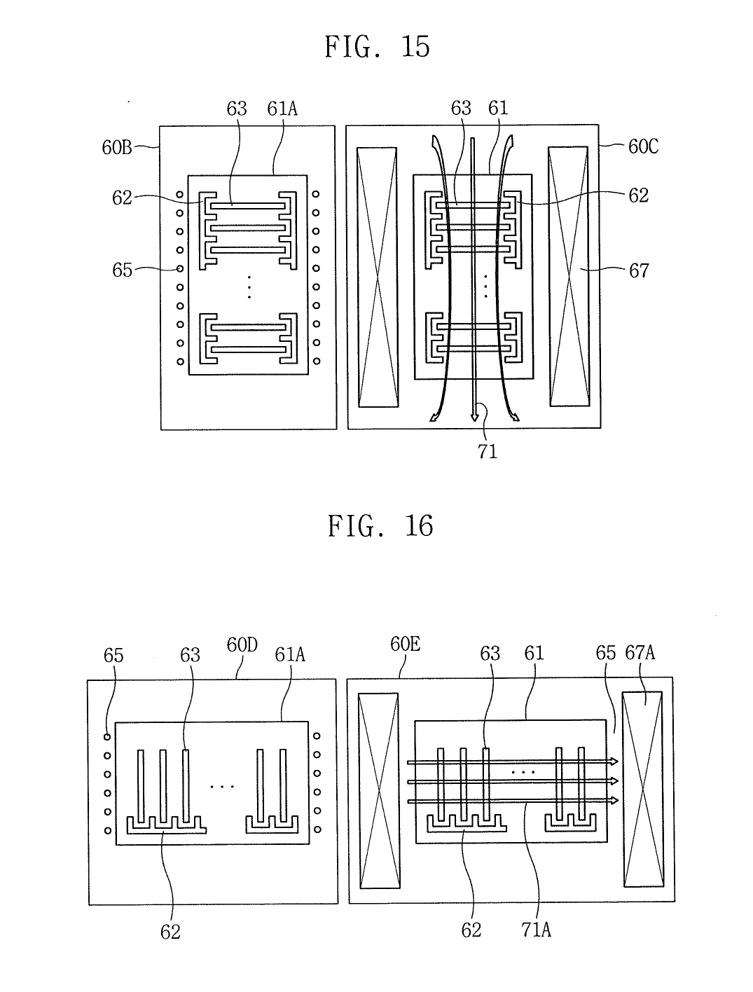

Referring to FIG. 16, in accordance with another embodiment, equipment for forming the semiconductor device may include third equipment 60D and fourth equipment 60E. The third equipment 60D may include a first chamber 61A and a heating device 65. The fourth equipment 60E may include a second chamber 61 and a magnetic field generation device 67A. The third equipment 60D may omit the magnetic field generation device 67A, and the fourth equipment 60E may omit heating device 65.

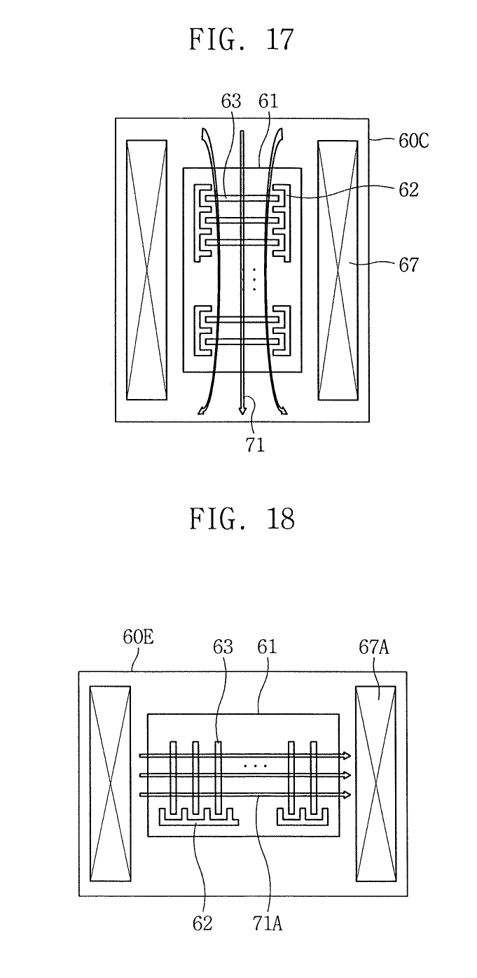

Referring to FIG. 17, equipment 60C may include a chamber 61 and a magnetic field generation device 67. The equipment 60C may omit the heating device 65, such as shown, for example, in FIG. 13.

Referring to FIG. 18, equipment 60E may include a chamber 61 and a magnetic field generation device 67A. The equipment 60E may omit the heating device 65, such as shown, for example, in FIG. 14.

Referring to FIGS. 1 and 7 to 13, the data storage plug DSP and the switching element SE may be formed in the wafers 63 (S100).

The data storage plug DSP may be serve as a spin valve magnetoresistance device whose spin direction (magnetization direction) has uniaxial magnetic anisotropy perpendicular to a film surface. The data storage plug DSP may be a perpendicular magnetized magnetic device using interface perpendicular anisotropy. The spin direction of the pinned layers 30 and 30A may be fixed in one direction perpendicular to an interface between the pinned layers 30 and 30A and the barrier layer 40. The spin direction of the free layers 50, 50A, and 50B may be perpendicular to an interface between the free layers 50, 50A, and 50B and the barrier layer 40, and may be the same as the spin direction of the pinned layers 30 and 30A or opposite to the spin direction of the pinned layers 30 and 30A.

The data storage plug DSP may exhibit a low resistance when the spin direction of the free layers 50, 50A, and 50B is the same spin direction as that of the pinned layers 30 and 30A. The data storage plug DSP may exhibit a high resistance when the spin direction of the free layers 50, 50A, and 50B is opposite to that of the pinned layers 30 and 30A. A magnetoresistance ratio of the data storage plug DSP may be represented by (high resistance−low resistance)/low resistance×100 (%). Increasing a magnetoresistance ratio of the data storage plug DSP may be more suitable to the use of a memory device for some applications.

The wafers 63 vertically mounted in the magazine 62 may be loaded into the chamber 61. A first perpendicular magnetic field 71 may be applied to the wafers 63 to perform an annealing process (S110). The first perpendicular magnetic field 71 may be, for example, 0.01T to 5T or lie in another range in other embodiments. The annealing process may be performed at a temperature of, for example, 250° C. to 400° C. for 30 minutes to 24 hours, or in another temperature range and/or timing in other embodiments. The annealing process may be determined based on a crystallization temperature and time of the data storage plug DSP. For example, the annealing process may be performed at a temperature of about 275° C. for about 30 minutes.

The perpendicular magnetic field 71 may be applied in a direction perpendicular to a surface of the data storage plug DSP. The perpendicular magnetic field 71 may be applied in a direction perpendicular to an interface between the free layers 50, 50A, and 50B and the barrier layer 40. The first perpendicular magnetic field 71 may be applied in a direction perpendicular to an interface between the pinned layers 30 and 30A and the barrier layer 40.

A second perpendicular magnetic field may be applied to the wafers 63 (S120). The second perpendicular magnetic field may have similar intensity to the first perpendicular magnetic field 71. The second perpendicular magnetic field may be applied in a direction perpendicular to the surface of the data storage plug DSP. The second perpendicular magnetic field may be applied in a direction perpendicular to an interface between the free layers 50, 50A, and 50B and the barrier layer 40. The second perpendicular magnetic field may be applied in a direction perpendicular to an interface between the pinned layers 30 and 30A and the barrier layer 40.

The first perpendicular magnetic field 71 may be applied to the wafers 63 to perform an annealing process (S110), and the application of the second perpendicular magnetic field to the wafers 63 (S120) may be performed using an in-situ process in the chamber 61. According to experimental embodiments, it was observed that a magnetoresistance ratio of the data storage plug DSP in the wafers 63 was significantly increased. In some embodiments, it was confirmed that the first perpendicular magnetic field 71 applied to the wafers 63 to perform an annealing process (S110) and the application of the second perpendicular magnetic field to the wafers 63 (S120) increased a magnetoresistance ratio of the data storage plug DSP by 1.5 times or more.

In other embodiments, application of the first perpendicular magnetic field 71 to perform an annealing process (S110) and application of the second perpendicular magnetic field (S120) may be sequentially performed using different equipment. In still other embodiments, application of the first perpendicular magnetic field 71 to perform an annealing process (S110) and application of the second perpendicular magnetic field (S120) may be performed using equipment 60A similar to that illustrated in FIG. 14.

In other embodiments, the application of the second perpendicular magnetic field (S120) may be omitted. For example, as described with reference to FIG, 3, a method of fabricating a semiconductor device according to one or more embodiments may include forming a perpendicular magnetized magnetic device (S100), and applying a perpendicular magnetic field to perform an annealing process (S110).

Referring to FIGS. 2, 7 to 12, and 15, the data storage plug DSP and the switching element SE may be formed in the wafers 63 (S100). The wafers 63, vertically mounted in the magazines 62, may be loaded into the first chamber 61A of the first equipment 60B. The heating device 65 may be disposed around the first chamber 61A, and the magnetic field generation device 67 may be omitted around the first chamber 61A. An annealing process may be performed on the wafers 63 (S111). The annealing process may be performed, for example, at a temperature of 250° C. to 400° C. for 30 minutes to 24 hours.

When the annealing process is completed, the wafers 63 may be loaded into the second chamber 61 of the second equipment 60C. The magnetic field generation device 67 may be disposed around the second chamber 61, and the heating device 65 may be omitted around the second chamber 61. A perpendicular magnetic field 71 may be applied to the wafers 63 (S120). The perpendicular magnetic field 71 may be applied in a direction perpendicular to an interface between the free layers 50, 50A, and 50B and the barrier layer 40. The perpendicular magnetic field 71 may be applied in a direction perpendicular to an interface between the pinned layers 30 and 30A and barrier layer 40.

In other embodiments, an annealing process on the wafers 63 (S111) and application of the perpendicular magnetic field 71 to the wafers 63 (S120) may be performed using the method described in FIG. 13, 14, 16, 17, or 18, or a combination thereof.

In other embodiments, the first chamber 61A of the first equipment 60B may include a device for forming a thin film constituting the data storage plug DSP. The formation of a thin film constituting the data storage plug DSP in the wafers 63 and performing an annealing process on the wafers 63 (S111) may be performed using an in-situ process in the first chamber 61A.

Referring to FIGS. 4, 7 to 12, and 17, the data storage plug DSP and the switching element SE may be formed in the wafers 63 (S100). An annealing process may be performed while a horizontal magnetic field is applied to the wafers 63 (S113). Various equipment may be applied to the application of a horizontal magnetic field to the wafers 63 and performing an annealing process (S113).

The wafers 63 may be loaded into the chamber 61 of the equipment 60C. The magnetic field generation device 67 may be disposed around the chamber 61 of the equipment 60C, and the heating device 65 (FIG. 13) may be omitted around the chamber 61 of the equipment 60C. A perpendicular magnetic field 71 may be applied to the wafers 63 (S120). The perpendicular magnetic field 71 may be applied in a direction perpendicular to an interface between the free layers 50, 50A, and 50B and the barrier layer 40. The perpendicular magnetic field 71 may be applied in a direction perpendicular to an interface between the pinned layers 30 and 30A and the barrier layer 40.

In other embodiments, application of the perpendicular magnetic field 71 to the wafers 63 (S120) may be performed using the method in FIG. 13, 14, 16, 17, or 18, or a combination thereof.

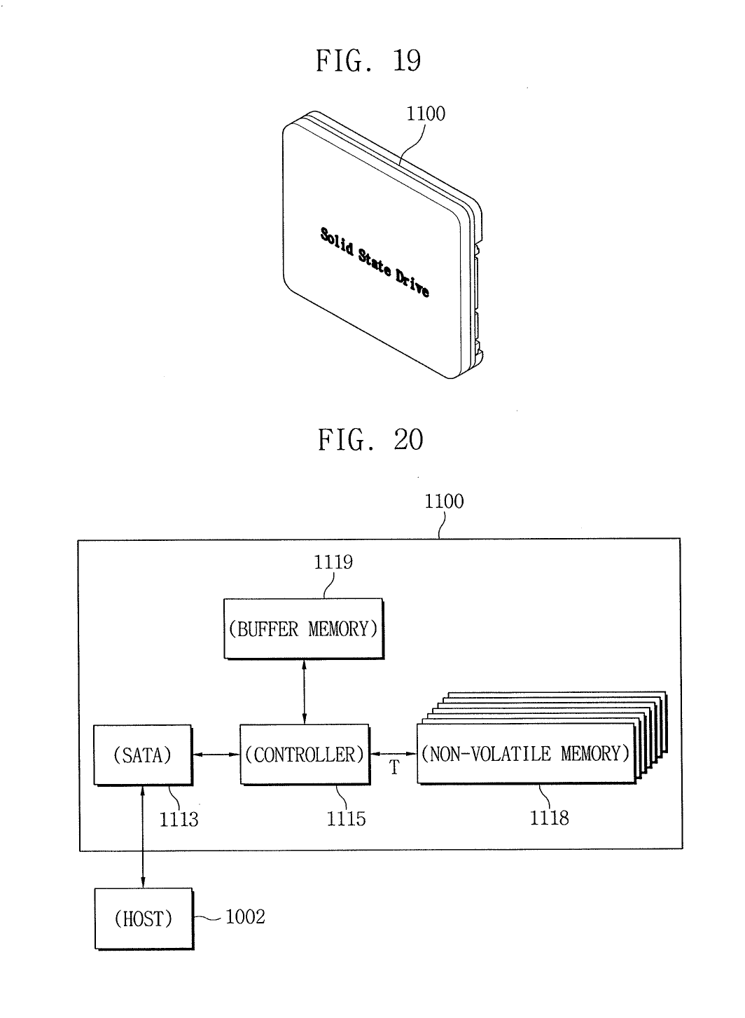

FIG. 19 illustrates an embodiment of an electronic device, and FIG. 20 illustrates a system block diagram of the electronic device. The electronic device may be, for example, a data storage device such as a solid state drive (SSD) 1100.

Referring to FIGS. 19 and 20, the SSD 1100 may include an interface 1113, a controller 1115, a non-volatile memory 1118, and a buffer memory 1119. The SSD 1100 is a device that stores information using a semiconductor device. The SSD 1100 is superior to a hard disk drive (HDD) in terms of speed, mechanical delay, error rate, generation of heat, noise, compact size, and light weight. The SSD 1100 may be used, for example, for a laptop computer, a notebook PC, a desktop PC, a MP3 player, or a portable storage device.

The controller 1115 may be formed adjacent the interface 1113 and electrically connected thereto. The controller 1115 may be a microprocessor that includes a memory controller and a buffer controller. The non-volatile memory 1118 may be formed adjacent the controller 1115 and electrically connected thereto. A data storage capacity of the SSD 1100 may correspond to the non-volatile memory 1118. The buffer memory 1119 may be formed to be adjacent to the controller 1115 and to be electrically connected thereto.

The interface 1113 may be connected to a host 1002 and may function to transmit and receive electrical signals such as data. For example, the interface 1113 may be a device that uses a standard such as SATA, IDE, or SCSI, or a combination thereof. The non-volatile memory 1118 may be connected to the interface 1113 via the controller 1115. The non-volatile memory 1118 may function to store data received via the interface 1113. The non-volatile memory 1118 is characterized by maintaining data stored therein even when power supplied to the SSD 1100 is completely cut off.

The buffer memory 1119 may include a volatile memory. The volatile memory may be a dynamic random access memory (DRAM) and/or a static random access memory (SRAM). The buffer memory 1119 may exhibit a faster operating rate than the non-volatile memory 1118 in some embodiments.

A data processing rate of the interface 1113 may be faster than the operating rate of the non-volatile memory 1118. The buffer memory 1119 may function to preliminarily store data. The data received via the interface 1113 may be preliminarily stored in the buffer memory 1119 via the controller 1115, and may keep pace with a data writing rate of the non-volatile memory 1118 to be permanently stored in the non-volatile memory 1118. Moreover, data frequently used among data stored in the non-volatile memory 1118 may be read in advance to be preliminarily stored in the buffer memory 1119. That is, the buffer memory 1119 may function to increase an effective operating rate of the SSD 1100 and to reduce an error rate.

The non-volatile memory 1118 may have a similar constitution to that described in FIGS. 1 to 18. For example, the non-volatile memory 1118 may include the data storage plug DSP as shown in FIG. 7.

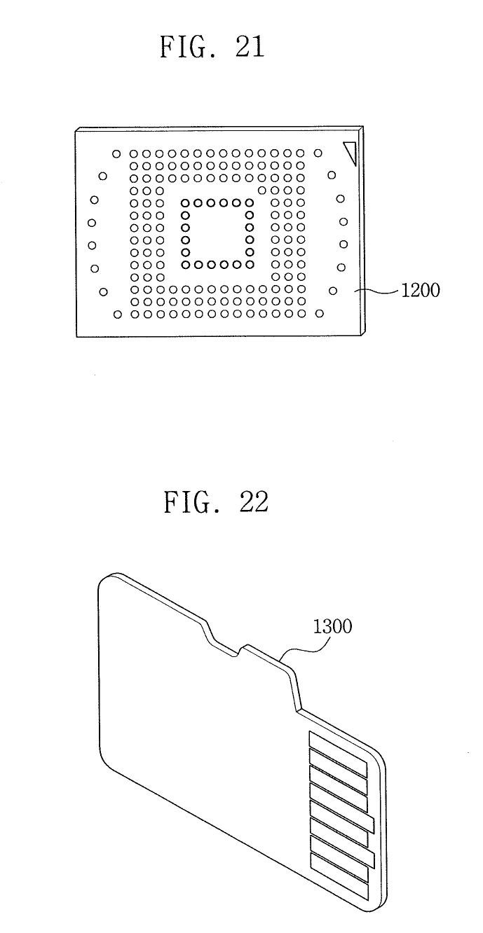

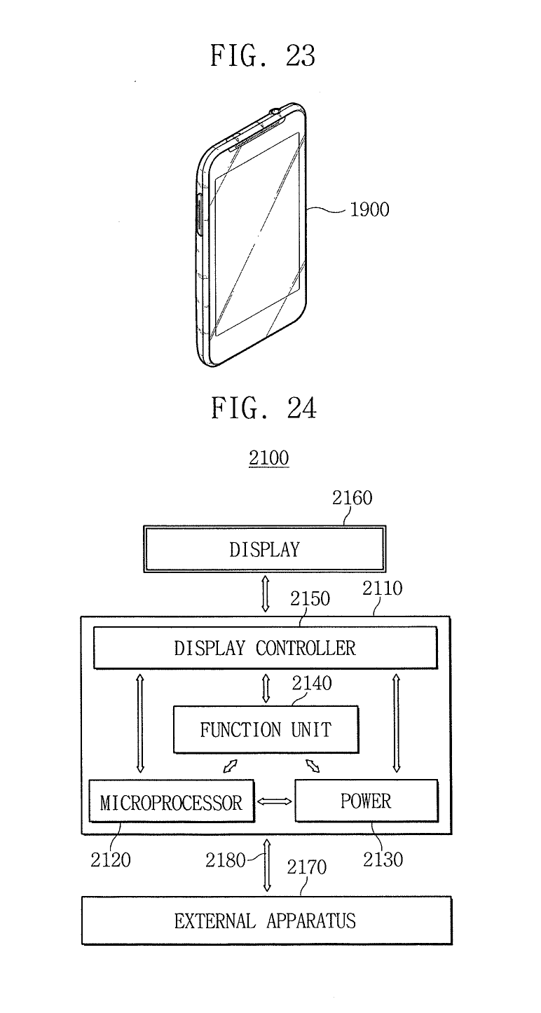

FIGS. 21 to 23 illustrate embodiments of an electronic device, and FIG. 24 illustrates a system block diagram of this electronic device. Referring to FIGS. 21 to 23, a semiconductor device described with reference to FIGS. 1 to 18 may be effectively used for electronic systems such as an embedded multi-media chip (eMMC) 1200, a micro SD 1300, a smartphone 1900, a netbook, a notebook PC, or a tablet PC. For example, a semiconductor device similar to that described with reference to FIGS. 1 to 18 may be mounted on a mainboard in the smart phone 1900. A semiconductor device similar to that described with reference to FIGS. 1 to 18 may be provided as an extension device such as the micro SD 1300 to be combined with the smartphone 1900 and to be used.

Referring to FIG. 24, a semiconductor device similar to that described with reference to FIGS. 1 to 18 may be applied to an electronic system 2100. The electronic system 2100 may include a body 2110, a microprocessor unit 2120, a power unit 2130, a function unit 2140, and a display controller unit 2150. The body 2110 may be a motherboard formed of a printed circuit board therein. The microprocessor unit 2120, the power unit 2130, the function unit 2140, and the display controller unit 2150 may be mounted on the body 2110. A display unit 2160 may be disposed in or on a surface of the body 2110. For example, the display unit 2160 may display an image processed by the display controller unit 2150 disposed on the surface of the body 2110.

The power unit 2130 is supplied with a predetermined voltage from an external battery, and may divide the voltage into a required voltage level to supply to the microprocessor unit 2120, the function unit 2140, and the display controller unit 2150. The microprocessor unit 2120 receives a voltage from the power unit 2130 to control the function unit 2140 and the display unit 2160. The function unit 2140 may perform various functions of the electronic system 2100. For example, when the electronic system 2100 is a smartphone, the function unit 2140 may include various components capable of functioning as a cellular phone, such as dialing, outputting an image to the display unit 2160 through communication with an external apparatus 2170, and outputting voice through a speaker. When a camera is mounted, the function unit 2140 may include a camera image processor.

In one or more embodiments, when the electronic system 2100 is connected to a memory card for capacity expansion, function unit 2140 may include a memory card controller. The function unit 2140 may transmit and receive a signal to/from the external apparatus 2170 through a wired or wireless communication unit 2180. When the electronic system 2100 requires a universal serial bus (USB) for capacity expansion, the function unit 2140 may include an interface controller. Also, the function unit 2140 may include a large-capacity storage device.

A semiconductor device similar to that described with reference to FIGS. 1 to 18 may be applied to the function unit 2140 or the microprocessor unit 2120. For example, the function unit 2140 may include the data storage plug DSP (e.g., FIG. 7), and the data storage plug DSP (e.g., FIG. 7) may be electrically connected to the body 2110.

According to one or more embodiments, a method of forming a semiconductor device including annealing a perpendicular magnetized magnetic device and crystallizing the annealed results, and applying a perpendicular magnetic field to the perpendicular magnetized magnetic device can be provided. The perpendicular magnetized magnetic device may include a pinned layer, a free layer, and a barrier layer between the pinned layer and the free layer. The perpendicular magnetic field may be applied in a direction perpendicular to an interface between the free layer and the barrier layer, and the perpendicular magnetic field may be applied in a direction perpendicular to an interface between the pinned layer and the barrier layer. A magnetoresistance of the perpendicular magnetized magnetic device can be significantly increased.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A method of forming a semiconductor device, comprising:
forming a perpendicular magnetized magnetic device;
annealing the perpendicular magnetized magnetic device; and
applying a magnetic field to the perpendicular magnetized magnetic device, wherein the magnetic field is applied in a direction that is substantially perpendicular to a substrate coupled to the perpendicular magnetized magnetic device.

2. The method as claimed in claim 1, wherein applying the perpendicular magnetic field to the perpendicular magnetized magnetic device comprises:
applying a first perpendicular magnetic field; and
applying a second perpendicular magnetic field, wherein the first perpendicular magnetic field is applied simultaneously with the annealing of the perpendicular magnetized magnetic device.

3. The method as claimed in claim 1, wherein forming the perpendicular magnetized magnetic device and annealing the perpendicular magnetized magnetic device are performed using an in-situ process in a same chamber.

4. The method as claimed in claim 1, wherein the perpendicular magnetic field is performed after the annealing of the perpendicular magnetized magnetic device.

5. The method as claimed in claim 1, wherein annealing the perpendicular magnetized magnetic device and applying the perpendicular magnetic field to the perpendicular magnetized magnetic device are performed using an in-situ process in a same chamber.

6. The method as claimed in claim 1, wherein applying the perpendicular magnetic field and annealing the perpendicular magnetized magnetic device are performed simultaneously.

7. The method as claimed in claim 1, further comprising:
applying a horizontal magnetic field to the perpendicular magnetized magnetic device, wherein applying the horizontal magnetic field and annealing of the perpendicular magnetized magnetic device are performed simultaneously.

8. The method as claimed in claim 1, wherein the perpendicular magnetic field lies in a range of about 0.01T to about 5T.

9. The method as claimed in claim 1, wherein annealing the perpendicular magnetized magnetic device is performed at a temperature range of about 250° C. to about 400° C.

10. The method as claimed in claim 1, wherein the perpendicular magnetized magnetic device comprises:
a pinned layer;
a free layer facing the pinned layer; and
a barrier layer between the pinned layer and the free layer, wherein the perpendicular magnetic field is applied in a direction substantially perpendicular to an interface between the barrier layer and the free layer.

11. The method as claimed in claim 10, wherein the pinned layer includes:
a buffer layer; and
a perpendicular magnetic anisotropy layer, wherein the buffer layer is formed between the perpendicular magnetic anisotropy layer and the barrier layer.

12. The method as claimed in claim 10, wherein the free layer includes:
a first free layer;
a second free layer; and
an intermediate layer between the first free layer and the second free layer, wherein the first free layer is formed between the intermediate layer and the barrier layer.

13-20. (canceled)
